(19) United States
(12) Patent Application Publication
(10) Pub. No.: US 2018/0337645 A1
(43) Pub. Date: Nov. 22, 2018

(54) INVERTER AMPLIFIER COMPARATOR

(71) Applicant: Avnera Corporation, Beaverton, OR (US)

(72) Inventors: Garry N. Link, Pacific City, OR (US); Wai Lee, Portland, OR (US)

(21) Appl. No.: 15/983,610

(22) Filed: May 18, 2018

Related U.S. Application Data
(60) Provisional application No. 62/508,280, filed on May 18, 2017.

(51) Int. Cl. H03F 3/45

(52) U.S. Cl. CPC H03F 3/45179; H03F 2203/45102; H03F 2203/45631; H03F 2200/372

(57) ABSTRACT

A circuit can include a first current source, a second current source, and a differential inverter amplifier electrically coupled between the first current source and the second current source. The differential inverter amplifier can include a plurality of load resistors and a plurality of diode-connected metal oxide semiconductor (MOS) clamps configured to limit output swing and minimize common mode disturbances.

### CROSS-REFERENCE TO RELATED APPLICATIONS

This application claims the benefit of U.S. Provisional Patent Application No. 62/508,280, filed May 18, 2017 and entitled “INVERTER AMPLIFIER COMPARATOR,” the disclosure of which is incorporated herein by reference in its entirety.

### TECHNICAL FIELD

This disclosure relates to electrical amplifier circuits and, more particularly, to an inverter amplifier comparator.

### BACKGROUND

Certain previous architectures are configured for low noise, high speed differential amplifiers that act as a simple differential pair with load resistors and a differential inverter amplifier topology. For low noise high speed applications, simplicity may be useful because additional complexity may degrade noise performance, bandwidth, or both. For portable, battery operated devices, efficiently employing current may be useful.

FIG. 1 illustrates an example of a previous topology 100 incorporating a metal oxide semiconductor (MOS) differential pair for gain and resistive loads. This circuit provides low noise, reasonable gain, and high bandwidth. FIG. 2 illustrates alternating current (AC), noise, and transient performance 200 of the topology 100 illustrated by FIG. 1 for the device size and technology shown.

Whereas a differential pair with load resistors is a low noise topology, amplifier topologies using both negative channel MOS (NMOS) and positive channel MOS (PMOS) differential pair configurations may be employed. These inverter amplifier topologies may provide improvement in performance because the bias current is used to generate gain (gm) in both the NMOS and PMOS pairs. FIG. 3 illustrates an example of a previous differential inverter amplifier topology 300 in which the bias current flows through both the PMOS and NMOS differential pairs, effectively doubling the available gm for properly optimized device sizing. A replica bias circuit is used to set the NMOS and PMOS bias current. Here, vcm is externally set to vdd/2 and the replica bias circuit adjusts so that the gates of the PMOS & NMOS current sources are also at vdd.

The differential inverter amplifier 300 illustrated by FIG. 3 may be employed for a high signal limiting stage such as the clock buffer in the reference. However, there are severe problems that make such a system inadequate for a high speed low noise amplifier stage for an input signal with a large dynamic range. The comparator for a Successive Approximation Register (SAR) Analog to Digitial Converter (ADC) is one such application.

FIG. 4 shows results 400 demonstrating that the output common mode voltage is about 850 mV compared to a desired output common mode of vcm=vdd/2. Since the gates of both the NMOS and PMOS current sources are tied together at a node labeled vgn in FIG. 4, the voltage is near half of vdd. This makes the circuit sensitive to device parameters and difficult to balance at the desired output common mode voltage. FIG. 6 shows the results 600 of a Monte Carlo mismatch simulation and that the output common mode varies over a large portion of the supply range, which may cause the circuit to exhibit excessive variation of gain and bandwidth. Furthermore, the circuit may become inoperable at extremes of common mode voltage due to headroom issues.

In addition to the issue of excessive common mode variation, the circuit 300 illustrated by FIG. 3 may exhibit limiting behavior that is signal dependent, which is undesirable in a SAR application because such behavior may cause distortion. A comparison between FIGS. 4 and 5 shows that the output common mode voltage and the two common source nodes labeled vsp and vsn exhibit strikingly different behavior between the 30 mV and 500 mV input signal cases.

This circuit 300 has three different modes of operation depending on the input signal: a small signal with no limiting and the input devices operating in the active region; a medium signal with the input switch devices entering the triode region and acting as switches; and a large signal with the input devices acting as switches and the current sources entering the triode region due to low headroom. The small and medium signal modes may not be problematic, but the large signal mode where the current sources are being crushed should be avoided.

Embodiments of the disclosed technology address these and other limitations in the prior art.

### BRIEF DESCRIPTION OF THE DRAWINGS

FIG. 1 illustrates an example of a previous topology incorporating a metal oxide semiconductor (MOS) differential pair for gain and resistive loads.

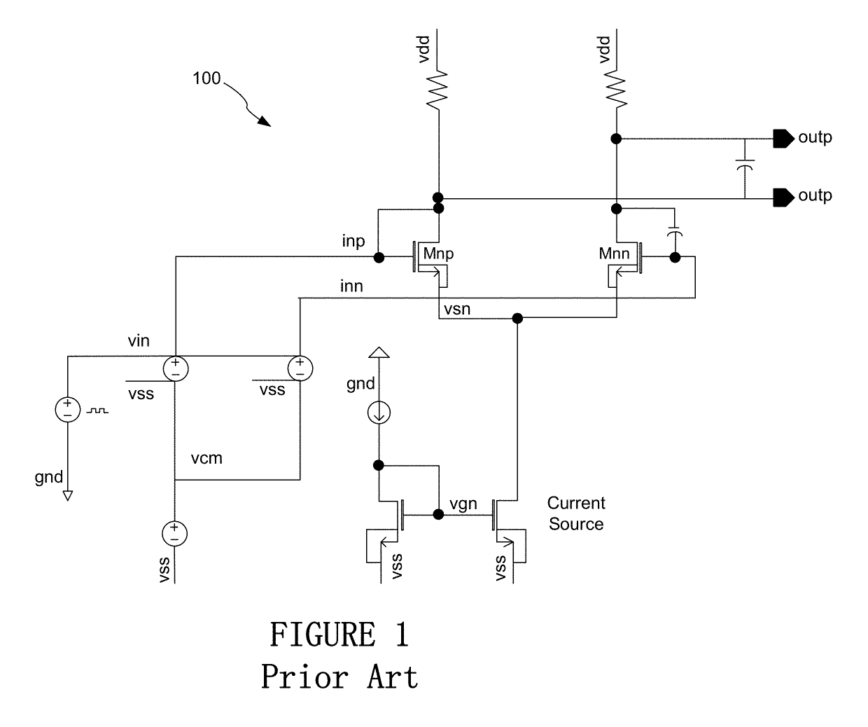

FIG. 2 illustrates alternating current (AC), noise, and transient performance of the topology illustrated by FIG. 1.

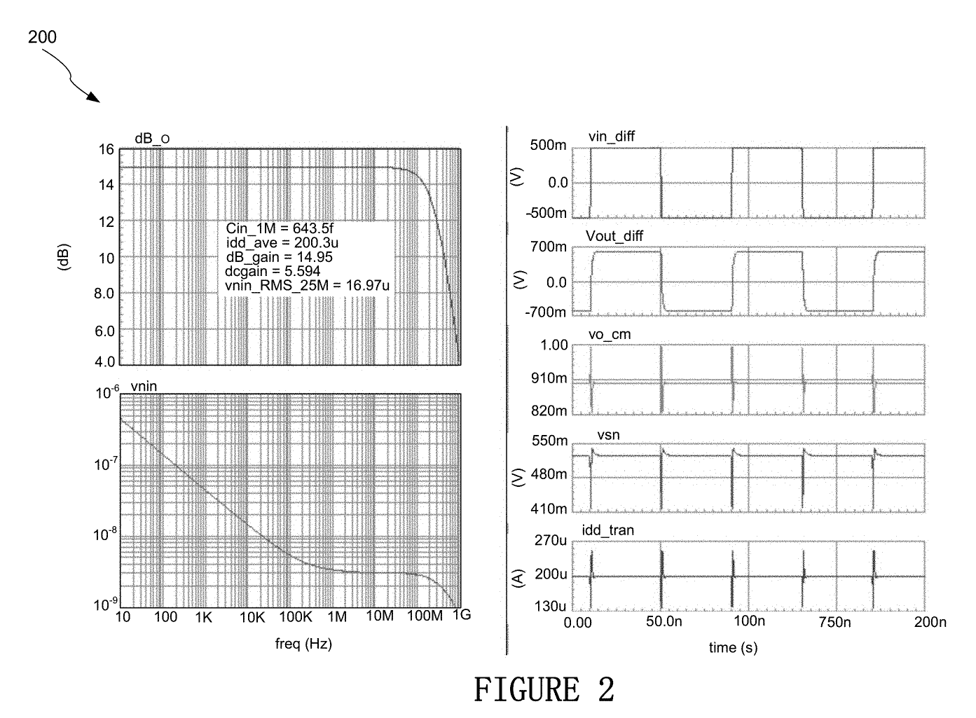

FIG. 3 illustrates an example of a previous differential inverter amplifier topology.

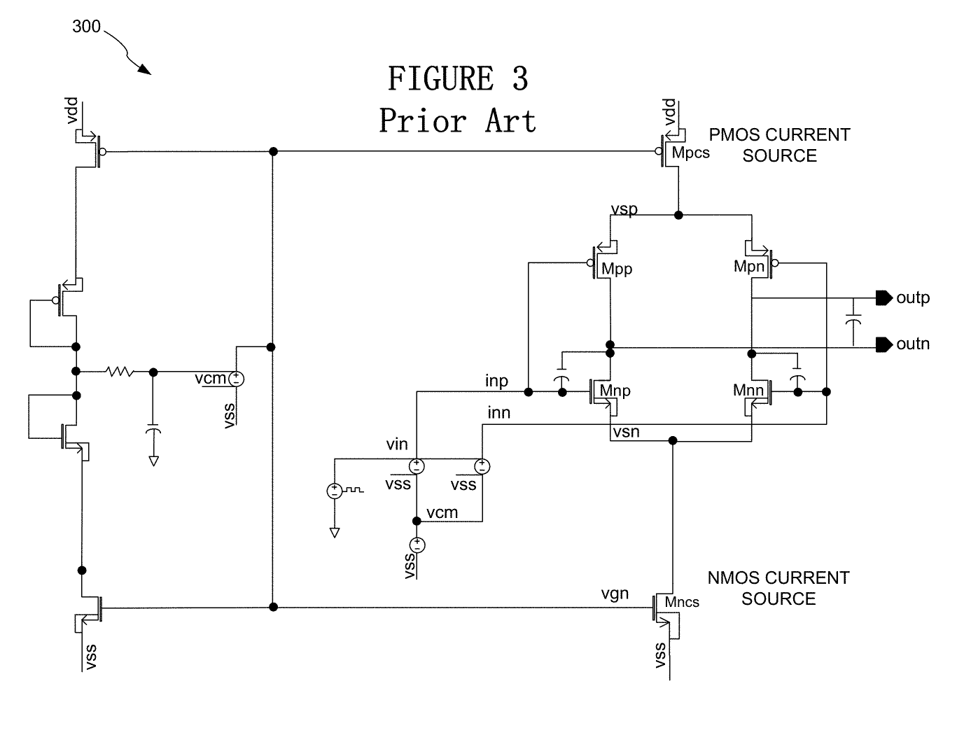

FIG. 4 illustrates an example of a small signal response of an inverter amplifier with replica bias.

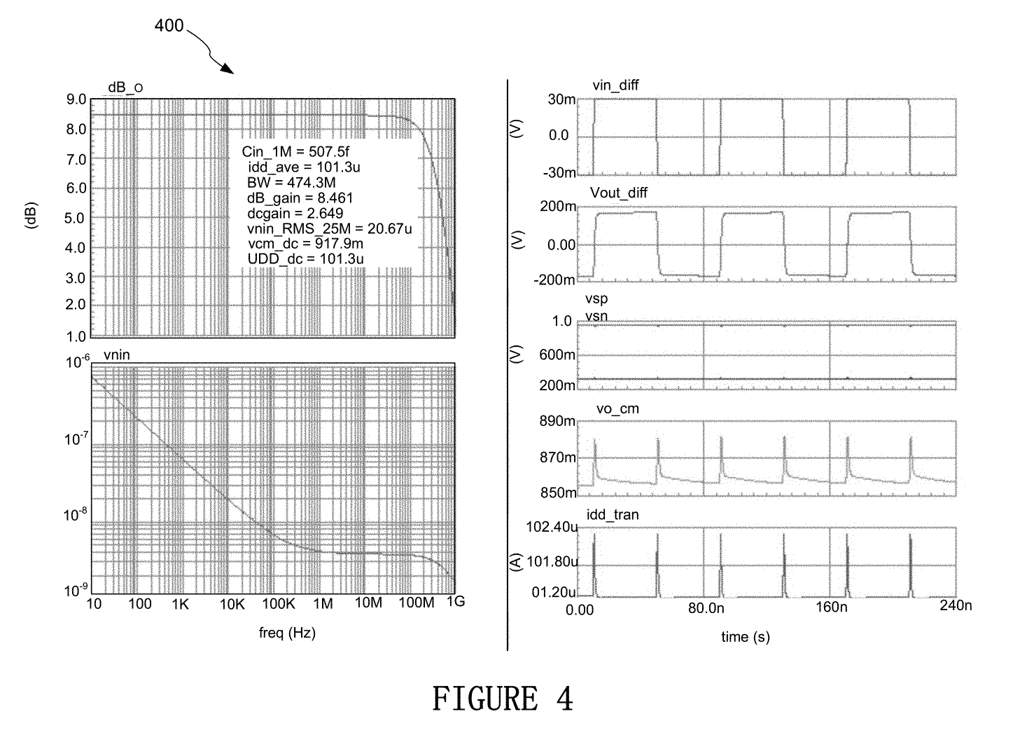

FIG. 5 illustrates an example of a large signal response of an inverter amplifier with replica bias.

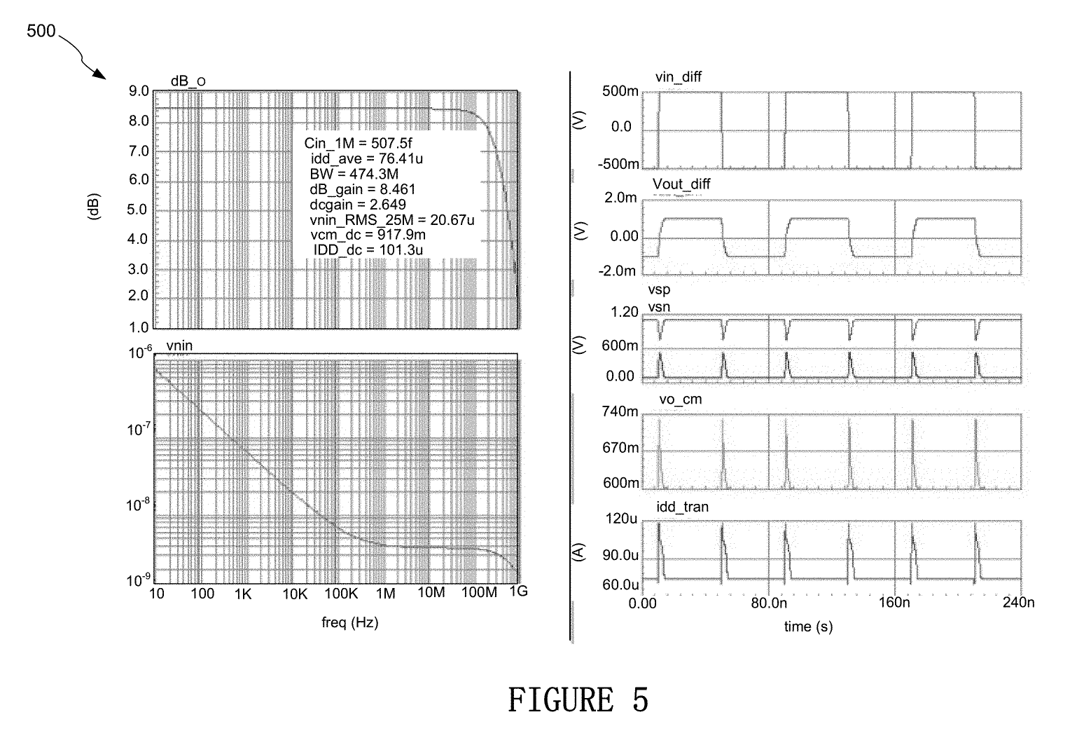

FIG. 6 illustrates an example of a Monte Carlo variation of an inverter amplifier with replica bias.

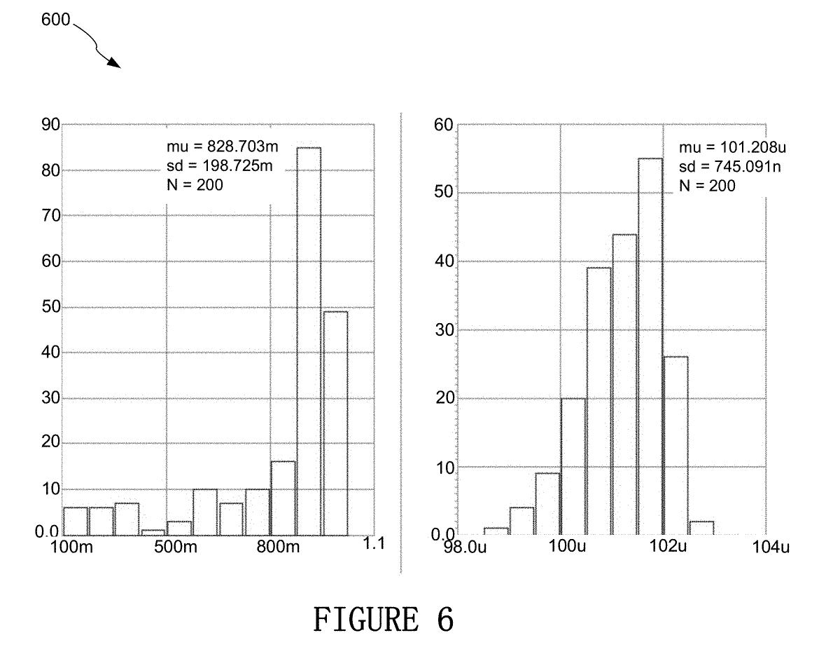

FIG. 7 illustrates an example of a differential inverter amplifier with separated common mode feedback of replica bias in accordance with certain embodiments of the disclosed technology.

FIG. 8 illustrates an example of a small signal response of the inverter amplifier with separated common mode feedback of replica bias illustrated by FIG. 7.

FIG. 9 illustrates an example of a large signal response of the inverter amplifier with separated common mode feedback of replica bias illustrated by FIG. 7.

FIG. 10 illustrates an example of a Monte Carlo variation of the inverter amplifier with separated common mode feedback of replica bias illustrated by FIG. 7.

FIG. 11 illustrates an example of a differential inverter amplifier with output common mode feedback in accordance with certain embodiments of the disclosed technology.

FIG. 12 illustrates an example of a small signal response of the inverter amplifier with output common mode feedback illustrated by FIG. 11.

FIG. 13 illustrates an example of a large signal response of the inverter amplifier with output common mode feedback illustrated by FIG. 11.

FIG. 14 illustrates an example of a Monte Carlo variation of the inverter amplifier with output common mode feedback illustrated by FIG. 11.

FIG. 15 illustrates an example of a differential inverter amplifier with output common mode feedback and load resistors in accordance with certain embodiments of the disclosed technology.

FIG. 16 illustrates an example of a small signal response of the inverter amplifier with output common mode feedback and load resistors illustrated by FIG. 15.

FIG. 17 illustrates an example of a large signal response of the inverter amplifier with output common mode feedback and load resistors illustrated by FIG. 15.

FIG. 18 illustrates an example of a differential inverter amplifier with load resistors connected to vcm=vdd/2 in accordance with certain embodiments of the disclosed technology.

FIG. 19 illustrates an example of a small signal response of the inverter amplifier with load resistors connected to vcm=vdd/2 illustrated by FIG. 18.

FIG. 20 illustrates an example of a large signal response of the inverter amplifier with load resistors connected to vcm=vdd/2 illustrated by FIG. 18.

FIG. 21 illustrates an example of a Monte Carlo variation of the inverter amplifier with output common mode feedback illustrated by FIG. 18.

FIG. 22 illustrates an example of a differential inverter amplifier with load resistors connected to vcm=vdd/2 and diode connected clamp devices in accordance with certain embodiments of the disclosed technology.

FIG. 23 illustrates an example of a small signal response of the inverter amplifier with load resistors connected to vcm=vdd/2 and diode connected clamp devices illustrated by FIG. 22.

FIG. 24 illustrates an example of a large signal response of the inverter amplifier with load resistors connected to vcm=vdd/2 and diode connected clamp devices illustrated by FIG. 22.

FIG. 25 illustrates an example of a Monte Carlo variation of the inverter amplifier with load resistors connected to vcm=vdd/2 and diode connected clamp devices illustrated by FIG. 22.

### DETAILED DESCRIPTION

Certain implementations of the disclosed technology address the common mode issues described above and provide output limiting to prevent the current sources from entering the triode region. In certain embodiments, a separate bias current setting and common mode voltage control may be employed. Diode-connected metal oxide semiconductor (MOS) clamps may be used to limit output swing and minimize common mode disturbances. A differential resistive load may be used to improve bandwidth and minimize common mode disturbances. A connection of load resistors may be used to cause a common mode voltage (vcm) equal to half of the voltage drain (vdd) in order to omit an output common mode control. A combination of load resistors and diode-connected clamps may be used to allow independent optimization of gain/bandwidth.

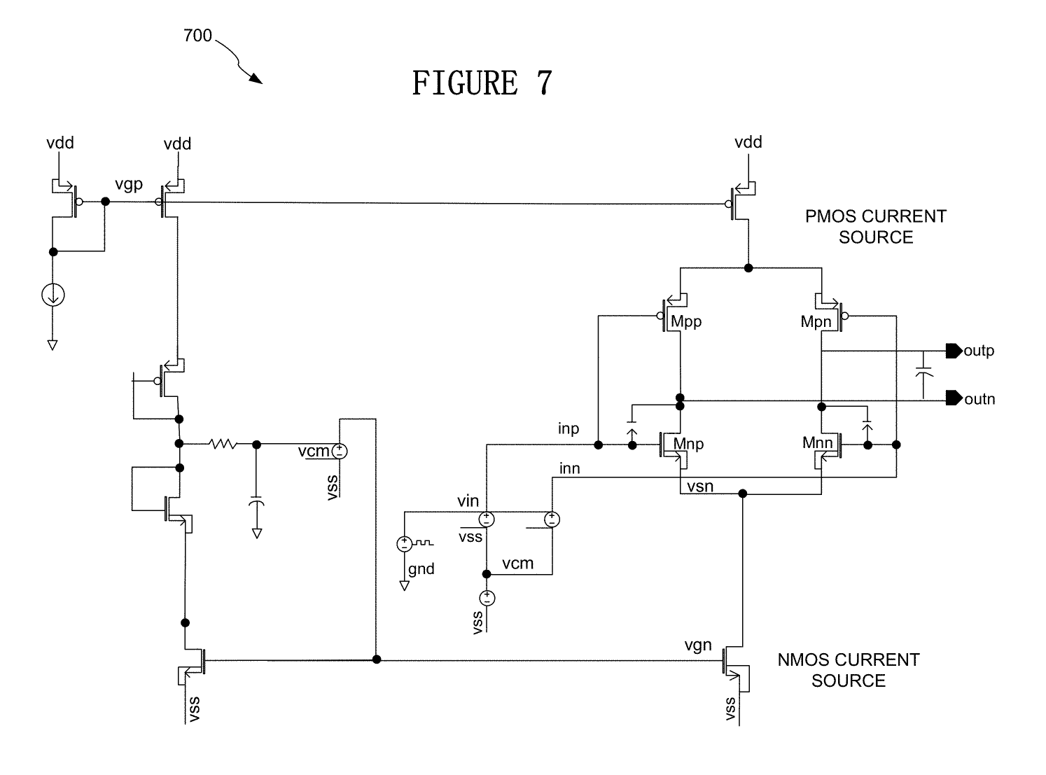

FIG. 7 illustrates an example of a differential inverter amplifier 700 with separated common mode feedback of replica bias in accordance with certain embodiments of the disclosed technology. In the example topology 700, the replica bias circuit has been separated into two parts: the first part is a PMOS mirror and current source connected to the PMOS differential pair, and the second part is a NMOS current source controlled by a feedback amplifier. The NMOS and PMOS current source nodes vgn and vgp may be separated so that one current source (here, the PMOS) provides the bias current, and the other current source (here, the NMOS) is adjusted by a feedback loop to set the common mode voltage.

In this example 700, the common mode voltage vcm is externally connected to vdd/2 and the circuit 700 is configured to adjust the center of the replica bias to also be at vdd/2. The arrangement of the devices in the replica bias are intended to mimic the devices in the amplifier.

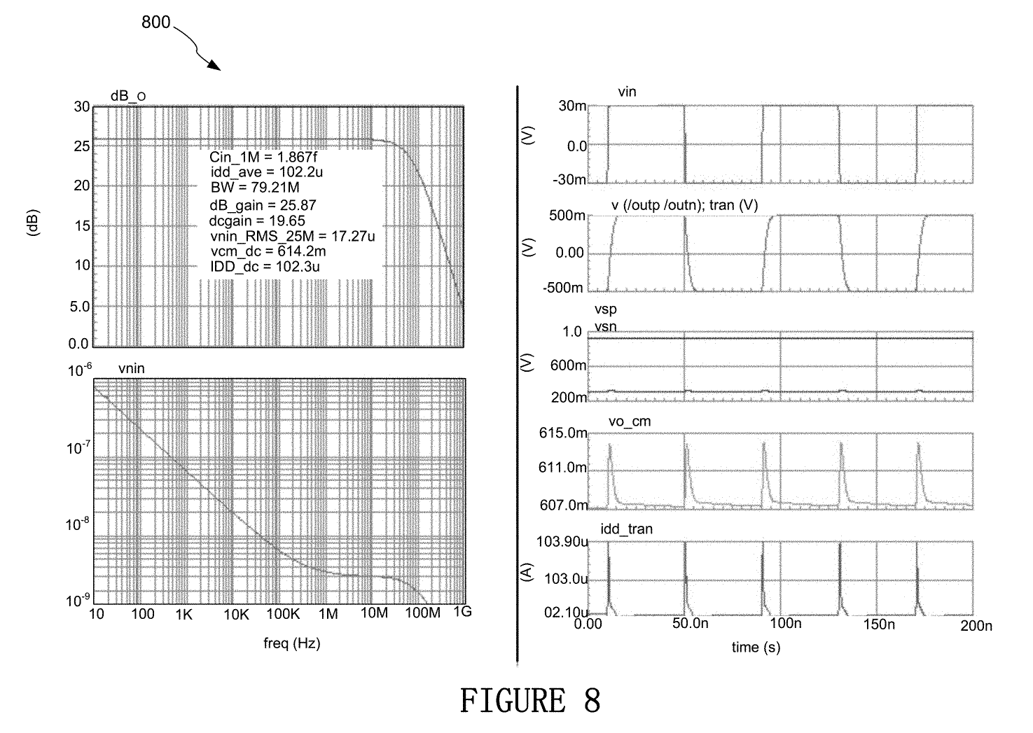

FIGS. 8, 9, and 10 illustrate example performance plots 800, 900, and 1000, respectively, that demonstrate that the output common mode may be balanced at vdd/2, but the circuit 700 still exhibits signal dependent limiting behavior and excessive Monte Carlo variation of output common mode. For a production circuit, the yield implication of such large variations may be problematic. The example shows that the two current sources are separated into one fixed current source and a second controlled source to set the common mode voltage.

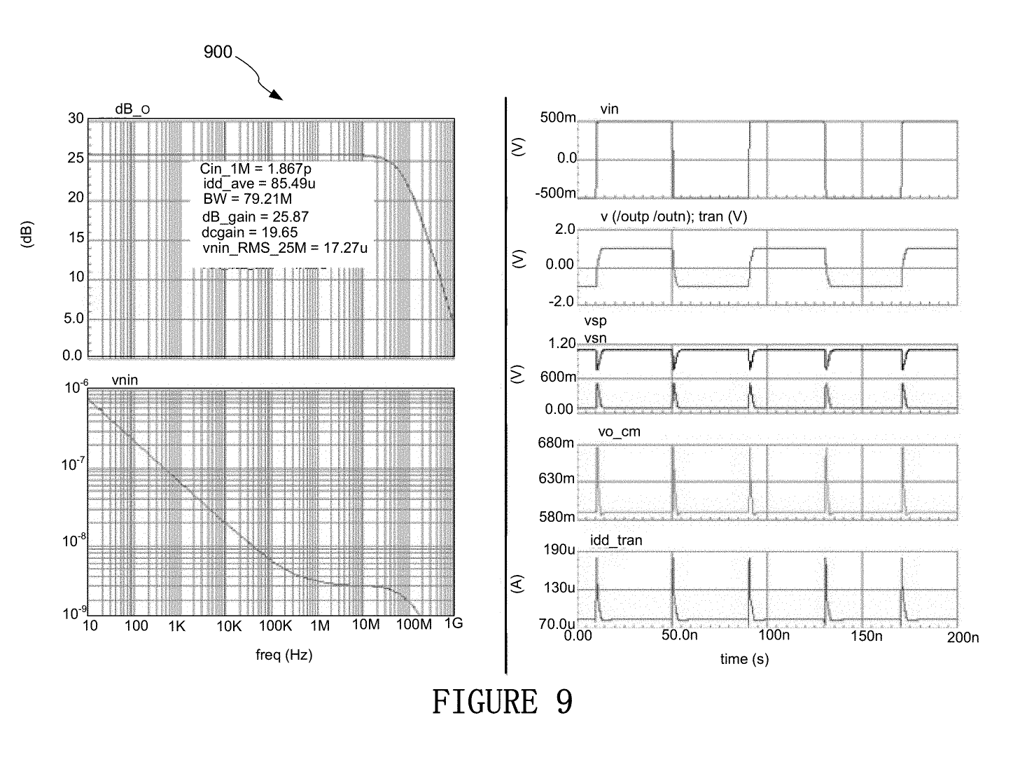

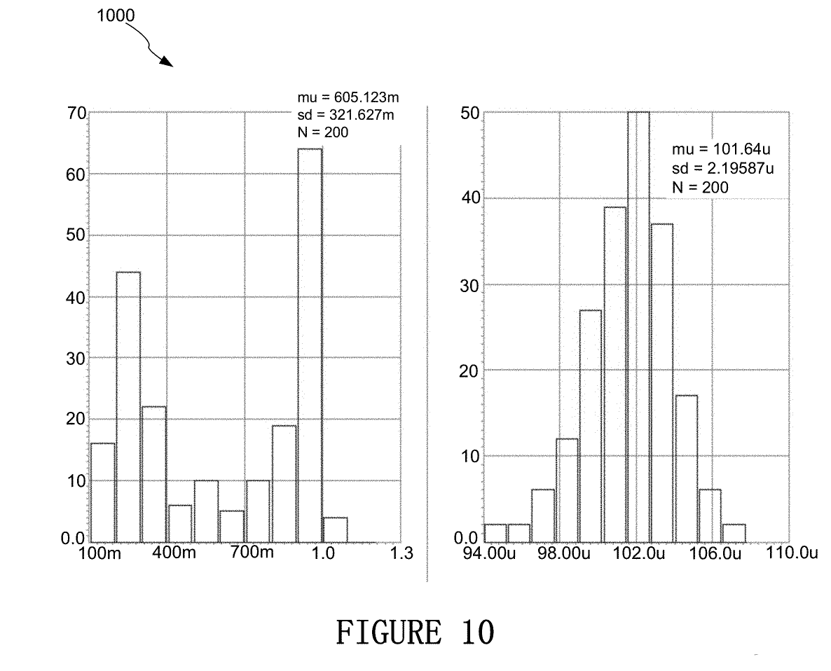

The plot 800 illustrated by FIG. 8 demonstrates that the circuit provides high gain, low bandwidth, and output common mode of 600 mV. The plot 900 illustrated by FIG. 9 demonstrates that the circuit exhibits high gain, low bandwidth, and output common mode variation. The plot 1000 illustrated by FIG. 10 demonstrates that the circuit may exhibit excessive output common mode variation.

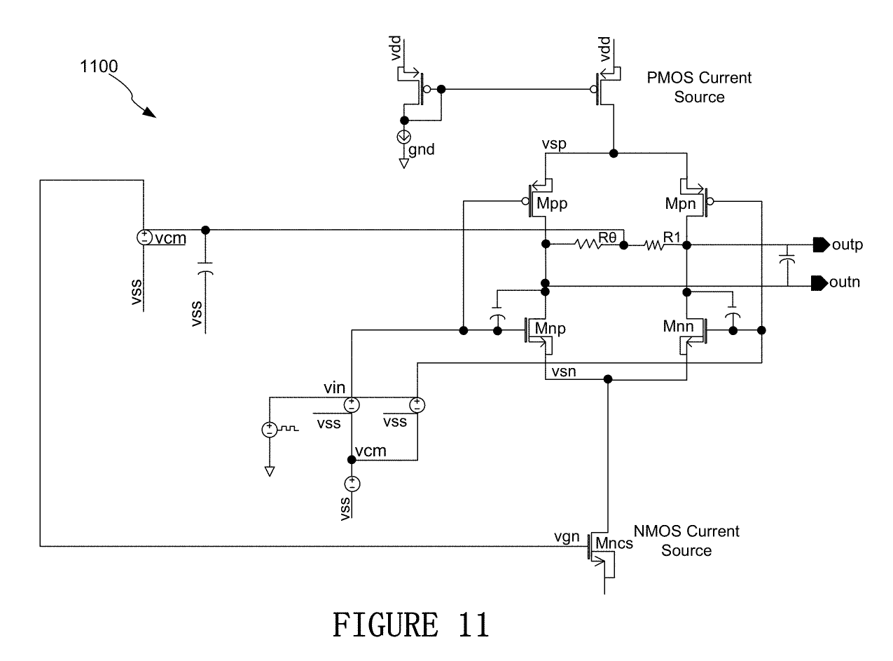

FIG. 11 illustrates an example of a differential inverter amplifier 1100 with output common mode feedback in accordance with certain embodiments of the disclosed technology. The topology 1100 illustrated by FIG. 11 includes a PMOS current source and an NMOS current source and output common mode feedback. In the example, the topology 1100 extends the concepts of the topology 700 illustrated by FIG. 7 by sensing the common mode at the actual output of the amplifier instead of at a replica bias circuit.

In this example 1100, the common mode voltage vcm is again connected to vdd/2 externally. But with this circuit 1100, the output common mode of the amplifier is configured to be directly sensed by the two large resistors such that the output common mode is adjusted to vdd/2 directly.

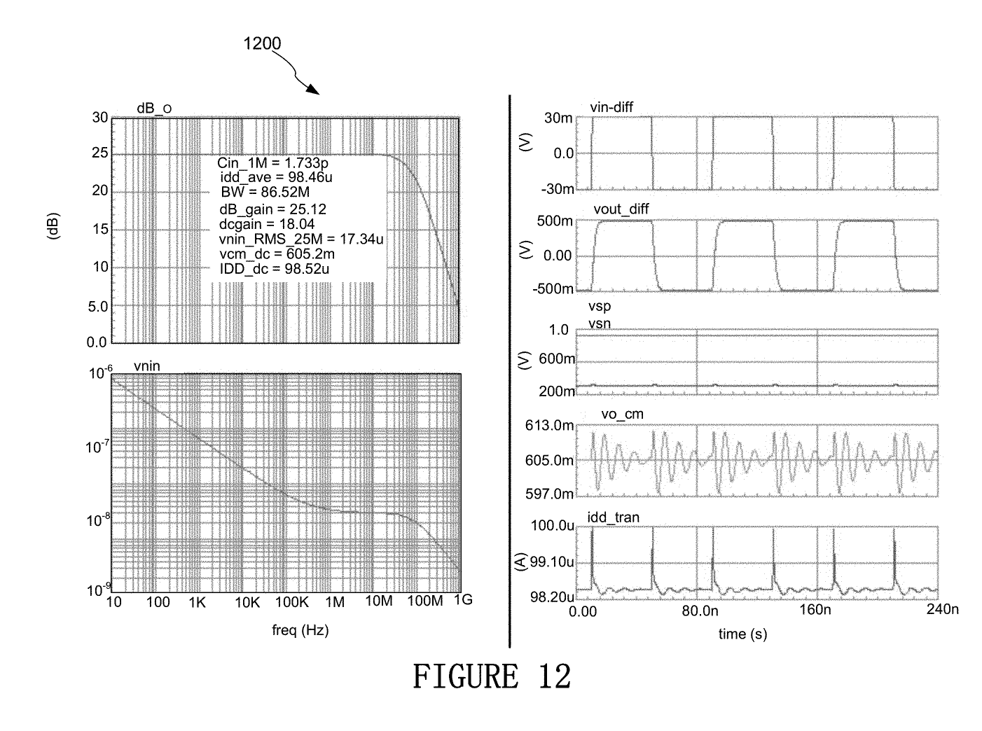

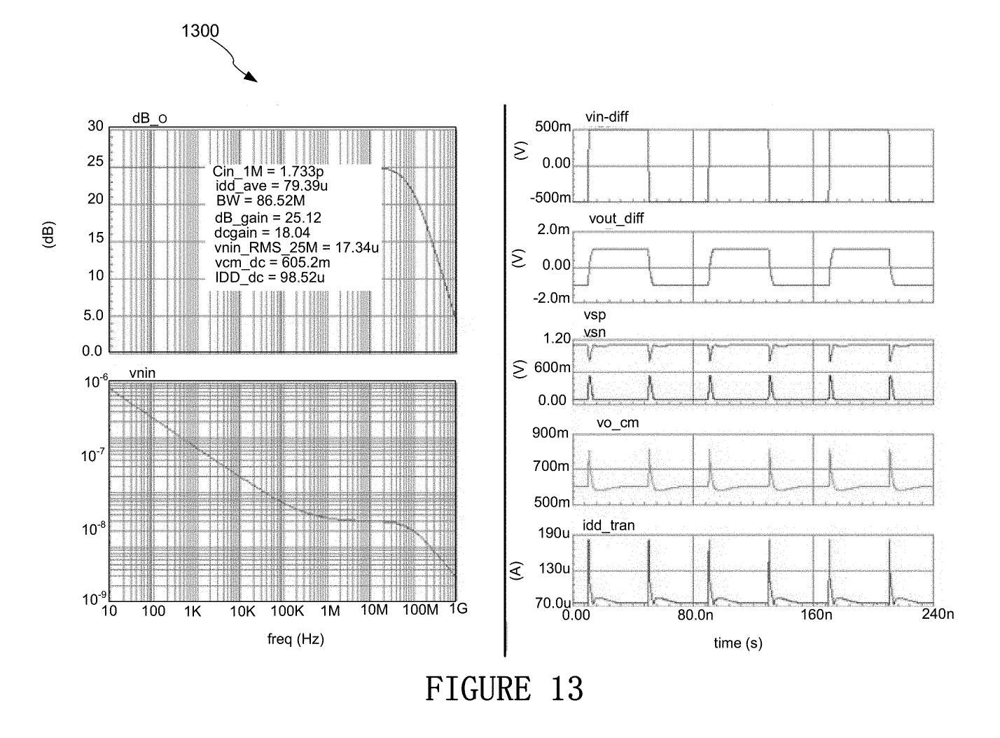

FIGS. 12, 13, and 14 illustrate performance plots 1200, 1300, and 1400, respectively, that demonstrate that the output common mode is centered at vcm=vdd/2 and now has reasonable Monte Carlo variation. However, FIG. 13 demonstrates that the current source nodes vsp and vsn are reaching supply and ground for large input signals. Stability of the common mode loop may also be a concern since the feedback becomes broken when the current sources run out of headroom.

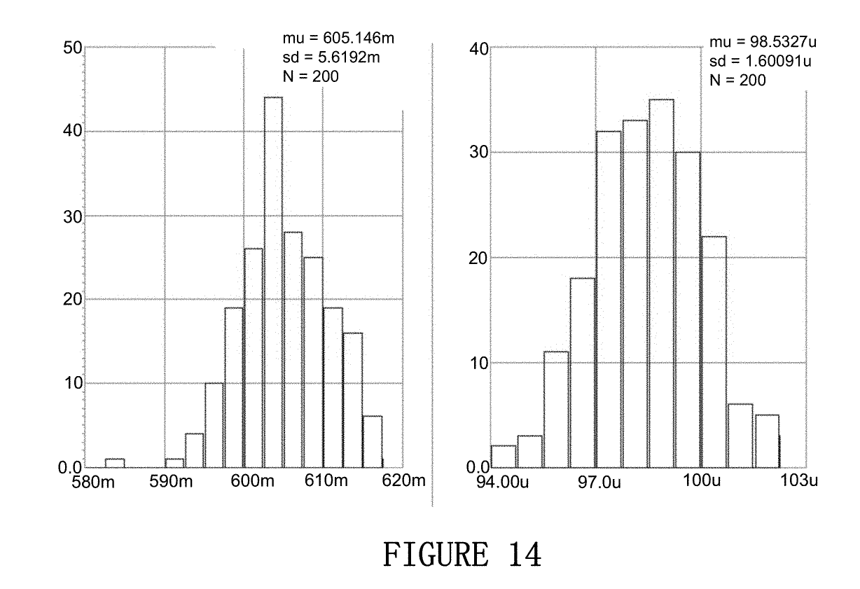

The plot 1200 illustrated by FIG. 12 demonstrates that that the circuit exhibits high gain, low bandwidth, and output common mode of 600 mV. The plot 1300 illustrated by FIG. 13 demonstrates that the circuit exhibits high gain, low bandwidth, and output common mode variation. The plot 1400 illustrated by FIG. 14 demonstrates that the circuit exhibits reasonable output common mode variation.

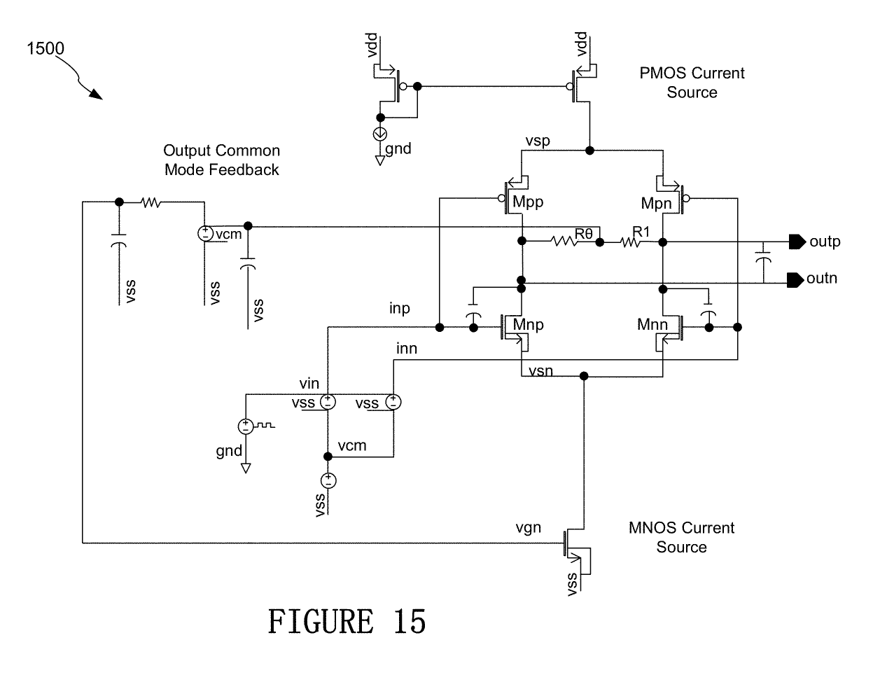

FIG. 15 illustrates an example of a differential inverter amplifier 1500 with output common mode feedback and load resistors in accordance with certain embodiments of the disclosed technology. In the example, the load resistors in the amplifier 1500 have been reduced from the high value common mode sensing resistors (e.g., the resistors in the circuit 1100 illustrated by FIG. 11) to a smaller value (e.g., 3 kiloohms (kohms)). This may limit the differential output voltage to the value of the bias current times twice the load resistor (e.g., (Vout_max=Ibias*2*Rload)). The maximum differential output swing may be set to a value sufficiently below the available supply voltage to provide headroom for both the NMOS and PMOS current sources.

Similar to the topology 1100 of FIG. 11, the common mode voltage vcm in this topology 1500 is connected to vdd/2 externally but the output common mode of the amplifier is configured to be directly sensed by the two large resistors such that the output common mode is adjusted to vdd/2 directly.

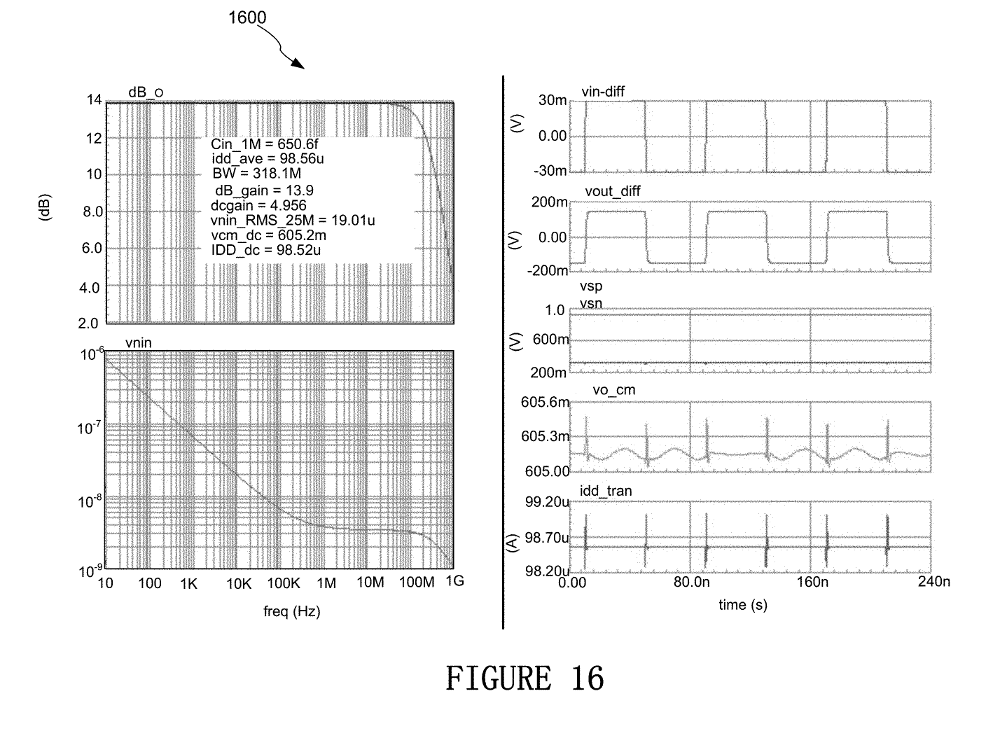

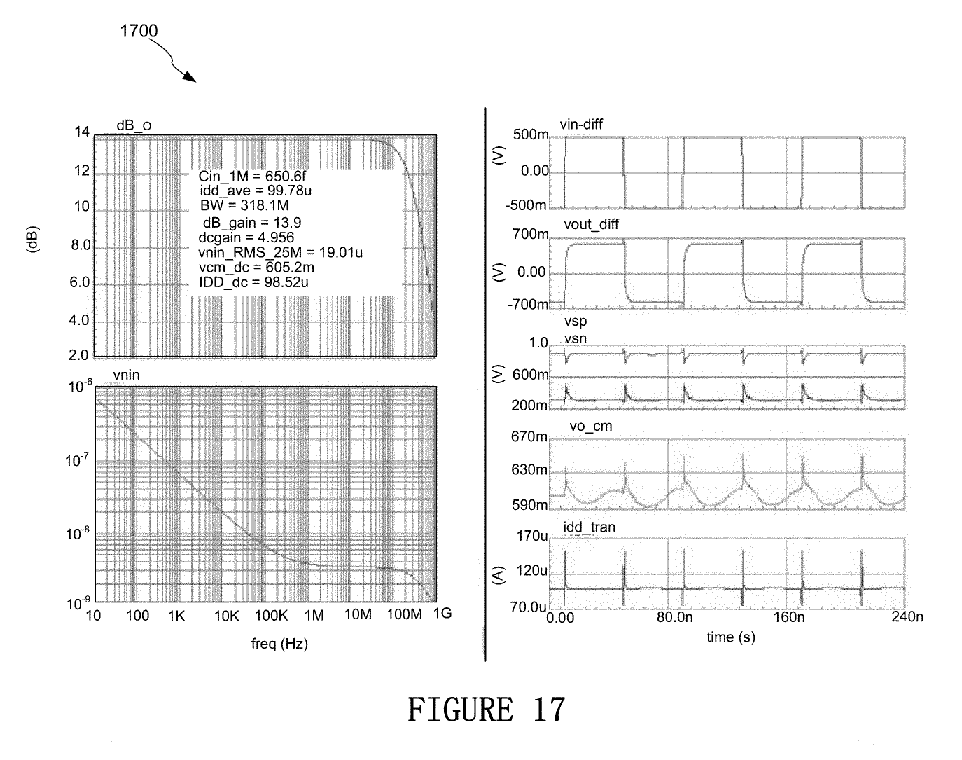

The performance plots 1600 and 1700 illustrated by FIGS. 16 and 17, respectively, show that the maximum output swing has been reduced, the bandwidth has been increased due to reduced gain, and the output common mode is now well controlled. The plot 1600 illustrated by FIG. 16 demonstrates that the circuit exhibits reduced gain, high bandwidth, and output common mode of 600 mV. The plot 1700 illustrated by FIG. 17 demonstrates that the circuit provides reduced gain, high bandwidth, and output common mode of 600 mV.

The circuit 1500 illustrated by FIG. 15 solves the common mode and limiting issues, but it still employs a common mode feedback circuit. The plots 1600 and 1700 of FIGS. 16 and 17, respectively, indicate that there may be some concerns that common mode response may disrupt the differential signal. There are methods to ensure sufficient common mode stability and minimize common mode perturbations. However, avoidance of a common mode feedback loop could be useful.

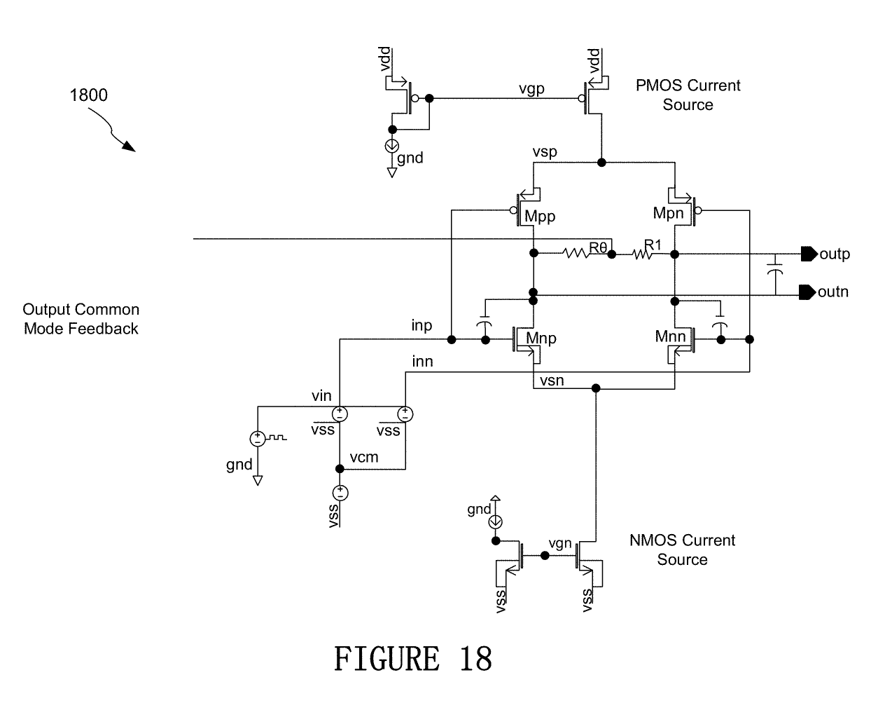

Successive Approximation Register (SAR) Analog-to-Digital Converters (ADCs) may have an externally filtered common mode voltage (vcm) available. FIG. 18, which illustrates an example of a differential inverter amplifier 1800 with load resistors connected to vcm=vdd/2 in accordance with certain embodiments of the disclosed technology, has been modified to connect the 3000 (3k) load resistors directly to vcm. This allows for the omission of a common mode feedback loop.

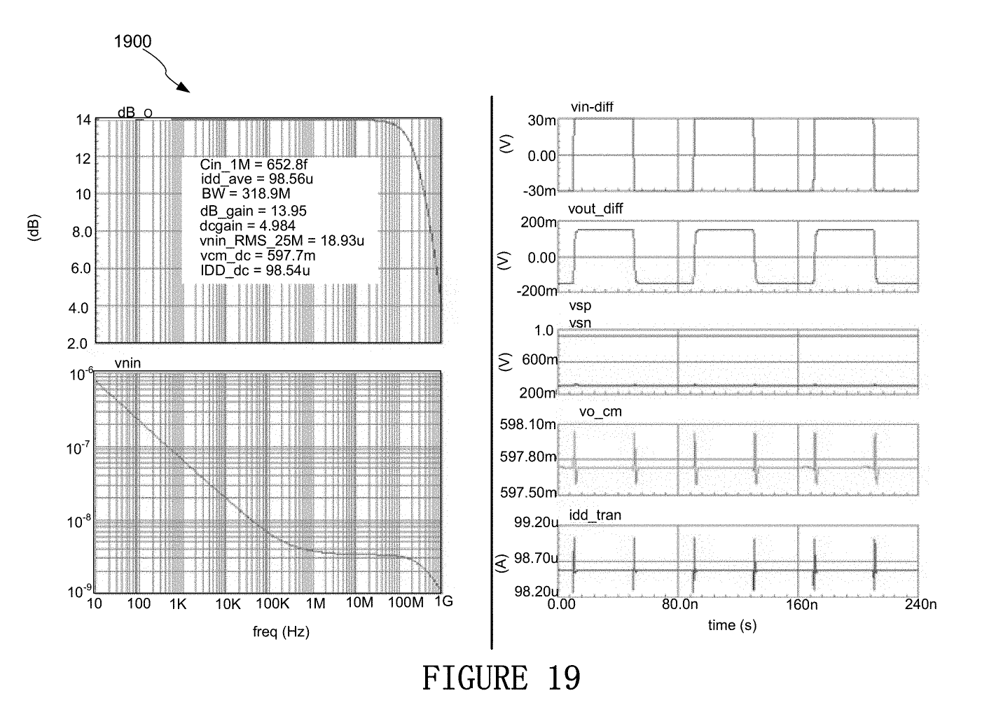

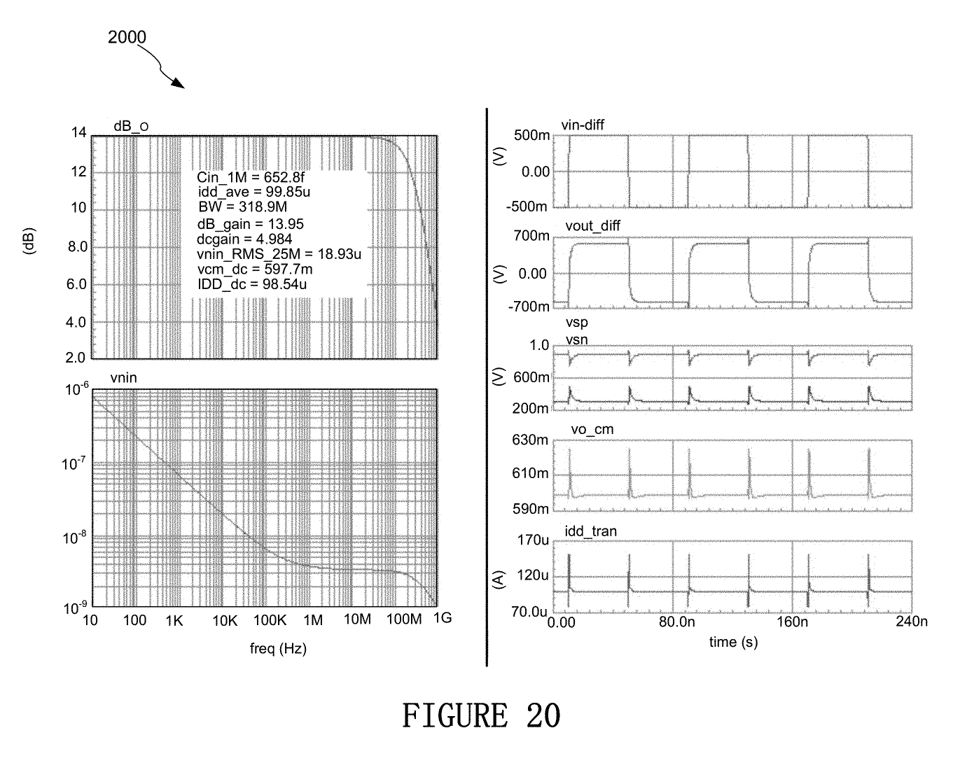

The performance plots 1900 and 2000 illustrated by FIGS. 19 and 20, respectively, demonstrate that the perturbations of the output common mode voltage and the common source nodes labeled vsp and vsn have been reduced considerably, e.g., compared to the plots 1600 and 1700 illustrated by FIGS. 16 and 17, respectively. The plot 1900 illustrated by FIG. 19 demonstrates that the circuit exhibits reduced gain, high bandwidth, and output common mode of 600 mV. The plot 2000 illustrated by FIG. 20 demonstrates that the circuit exhibits reduced gain, high bandwidth, and output common mode of 600 mV.

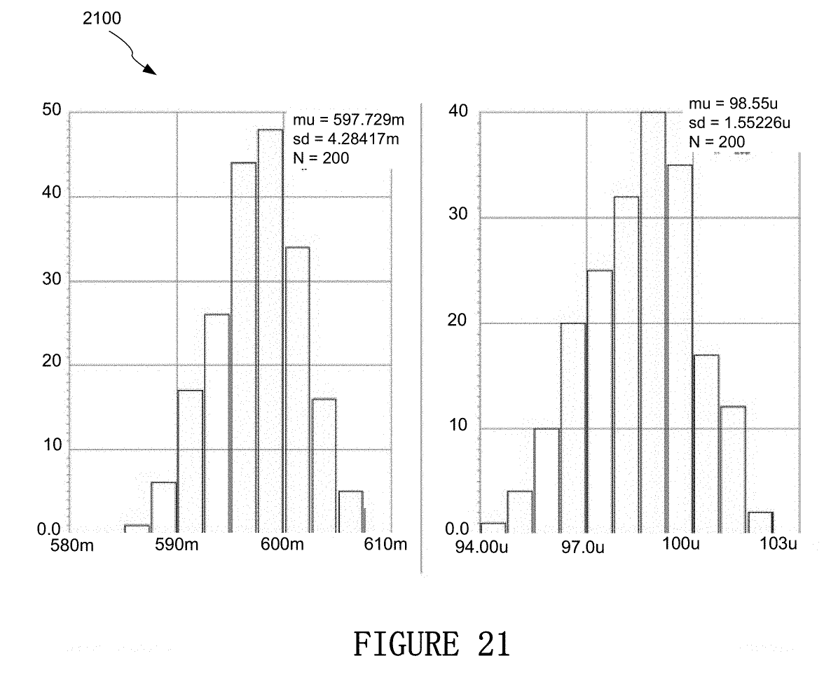

FIG. 21 illustrates an example of a Monte Carlo variation 2100 of the inverter amplifier 1800 with output common mode feedback illustrated by FIG. 18. The plot 2100 illustrated by FIG. 21 demonstrates that the circuit 1800 exhibits a reasonable output common mode variation.

The circuit 1800 illustrated by FIG. 18 may result in a reasonable performance for the gain stage in a SAR comparator. However, the gain may be constrained by the restriction of output voltage above (e.g., Vout_max=Ibias*2*Rload). The gain may be the total differential gm multiplied by twice Rload (e.g., Av=gm*2*Rload). The gm may be related to Ibias, so the maximum output voltage may constrain the gain.

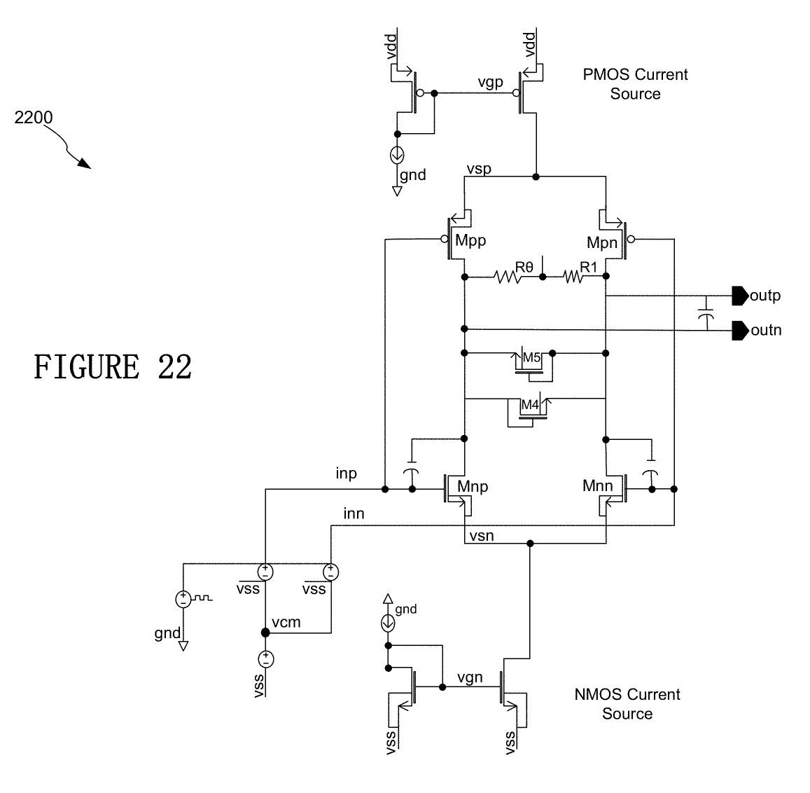

Mechanisms may be provided to allow for independently adjusting the gain to optimize gain, bandwidth, and noise of the circuit 1800. FIG. 22 illustrates an example of a differential inverter amplifier 2200 with load resistors connected to vcm=vdd/2 and diode connected clamp devices in accordance with certain embodiments of the disclosed technology. The addition of diode connected clamp devices in the circuit 2200 illustrated by FIG. 22 avoids the maximum output voltage constraint, and the load resistors can be increased as desired (e.g. 6 kohm in this case).

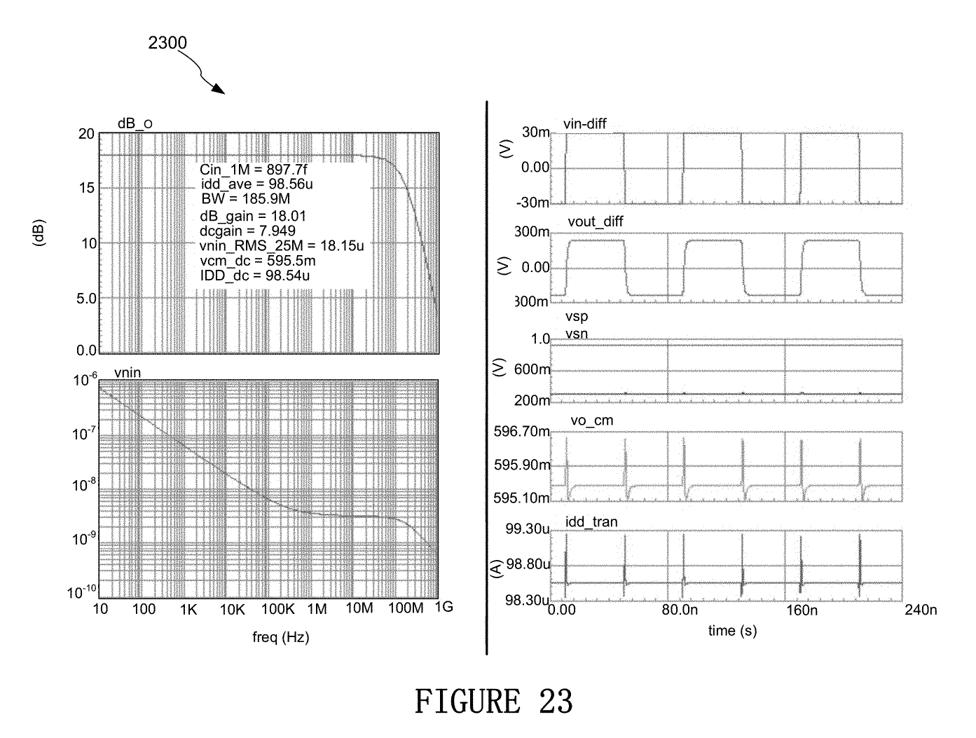

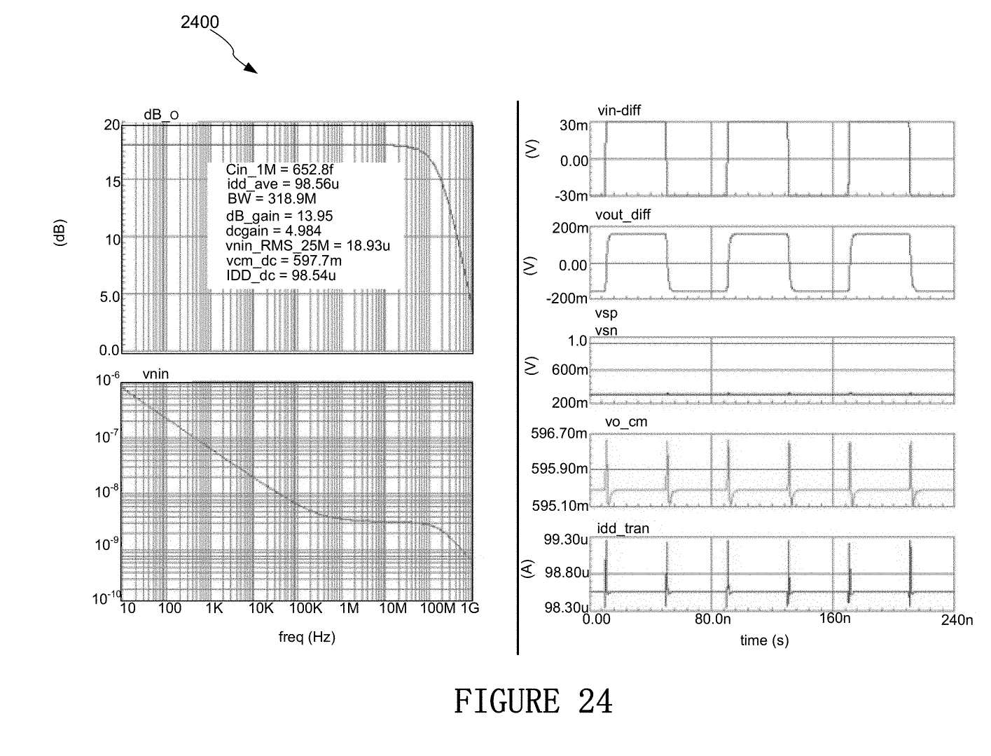

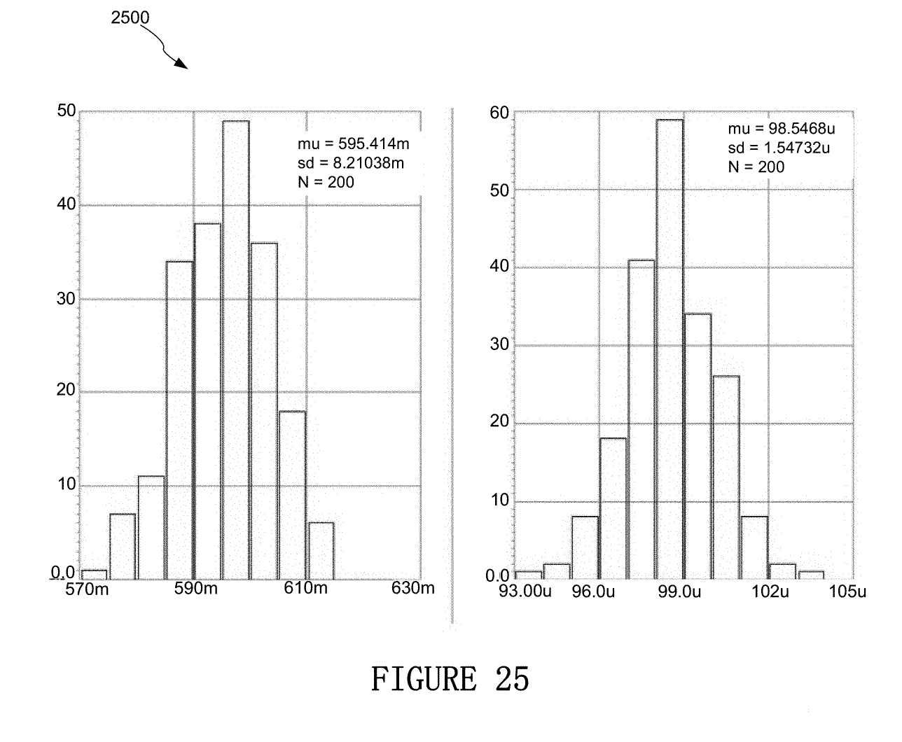

FIGS. 23 and 24 each illustrate the circuit response of the circuit 2200 and FIG. 25 shows a reasonable part-to-part variation of output common mode voltage. The plot 2300 illustrated by FIG. 23 demonstrates that the circuit 2200 exhibits reasonable gain, bandwidth, and output common mode. The plot 2400 illustrated by FIG. 24 demonstrates that the circuit 2200 provides reasonable gain, bandwidth, and output common mode. The plot 2400 further demonstrates that the circuit 2200 provides reduced output signal without sacrificing small signal gain and also has clean fast limiting (e.g., as compared to the plot 2000 illustrated by FIG. 20).

FIG. 25 illustrates an example of a Monte Carlo variation 2500 of the inverter amplifier 2200 with load resistors connected to vcm=vdd/2 and diode connected clamp devices illustrated by FIG. 22. The plot 2500 illustrated by FIG. 25 demonstrates that the circuit 2200 exhibits a reasonable output common mode variation.

Embodiments of the invention may be incorporated into integrated circuits such as sound processing circuits, or other audio circuitry. In turn, the integrated circuits may be used in audio devices such as headphones, mobile phones, portable computing devices, sound bars, audio docks, amplifiers, speakers, etc.

The previously described versions of the disclosed subject matter have many advantages that were either described or would be apparent to a person of ordinary skill. Even so, all of these advantages or features are not required in all versions of the disclosed apparatus, systems, or methods.

Additionally, this written description makes reference to particular features. It is to be understood that the disclosure in this specification includes all possible combinations of those particular features. For example, where a particular feature is disclosed in the context of a particular aspect or embodiment, that feature can also be used, to the extent possible, in the context of other aspects and embodiments.

Also, when reference is made in this application to a method having two or more defined steps or operations, the defined steps or operations can be carried out in any order or simultaneously, unless the context excludes those possibilities.

Furthermore, the term “comprises” and its grammatical equivalents are used in this disclosure to mean that other components, features, steps, processes, operations, etc. are optionally present. For example, an article “comprising” or “which comprises” components A, B, and C can contain only components A, B, and C, or it can contain components A, B, and C along with one or more other components.

Also, directions such as “right” and “left” are used for convenience and in reference to the diagrams provided in figures. But the disclosed subject matter may have a number of orientations in actual use or in different implementations. Thus, a feature that is vertical, horizontal, to the right, or to the left in the figures may not have that same orientation or direction in all implementations.

Although specific embodiments of the invention have been illustrated and described for purposes of illustration, it will be understood that various modifications may be made without departing from the spirit and scope of the invention. Accordingly, the invention should not be limited except as by the appended claims.

1. An apparatus, comprising:
a first current source;
a second current source; and
a differential inverter amplifier electrically coupled between the first current source and the second current source, the differential inverter amplifier including:
a plurality of load resistors; and
a plurality of diode-connected metal oxide semiconductor (MOS) clamps configured to limit output swing and minimize common mode disturbances.

2. The apparatus of claim 1, wherein the first current source is a positive channel MOS (PMOS) current source having a voltage vdd.

3. The apparatus of claim 2, wherein the second current source is a negative channel MOS (NMOS) current source having a voltage vss.

4. The apparatus of claim 3, further comprising a plurality of load resistors configured to provide a common mode voltage vcm that is equal to vdd/2.

5. The apparatus of claim 1, further comprising a differential resistive load to improve bandwidth and minimize common mode feedback control.

6. The apparatus of claim 4, wherein the plurality of diode-connected MOS clamps and the plurality of load resistors are configured to enable independent optimization of gain and bandwidth.

7. A system, comprising:
an input configured to receive an input voltage;
an output configured to provide an output voltage; and
a circuit electrically coupled between the input and the output, the circuit comprising:
a first current source;
a second current source; and
a differential inverter amplifier electrically coupled between the first current source and the second current source, the differential inverter amplifier including:
a plurality of load resistors; and
a plurality of diode-connected metal oxide semiconductor (MOS) clamps configured to limit output swing and minimize common mode disturbances.

8. The system of claim 7, wherein the first current source is a positive channel MOS (PMOS) current source having a voltage vdd.

9. The system of claim 8, wherein the second current source is a negative channel MOS (NMOS) current source having a voltage vss.

10. The system of claim 9, the circuit further comprising a plurality of load resistors configured to provide a common mode voltage vcm that is equal to vdd/2.

11. The system of claim 10, the circuit further comprising a differential resistive load to improve bandwidth and minimize common mode feedback control.

12. The system of claim 10, wherein the plurality of diode-connected MOS clamps and the plurality of load resistors are configured to enable independent optimization of gain and bandwidth.
